(19) United States
(12) Patent Application Publication
(10) Pub. No.: US 2016/0315089 A1
(43) Pub. Date: Oct. 27, 2016

(54) SEMICONDUCTOR MEMORY DEVICE

(71) Applicant: KABUSHIKI KAISHA TOSHIBA, Minato-ku (JP)

(72) Inventors: Takayuki Ito, Yokkaichi (JP); Yasunori Oshima, Yokkaichi (JP)

(73) Assignee: KABUSHIKI KAISHA TOSHIBA, Minato-ku (JP)

(21) Appl. No.: 14/796,438

(22) Filed: Jul. 10, 2015

Related U.S. Application Data
(60) Provisional application No. 62/153,283, filed on Apr. 27, 2015.

(51) Int. Cl. H01L 27/115

(52) U.S. Cl. CPC H01L 27/1158

(57) ABSTRACT

A laminated body is disposed on a semiconductor substrate made of silicon. The laminated body includes a plurality of conductive layers and an interlayer insulating film. The interlayer insulating layer is disposed between the plurality of conductive layers. A memory cell array includes a pillar-shaped semiconductor layer and a memory gate insulating film. A peripheral area of the semiconductor layer is surrounded by the laminated body. The semiconductor layer extends with a first direction as a longitudinal direction. The memory gate insulating film is disposed between the pillar-shaped semiconductor layer and the laminated body. The memory gate insulating film includes an electric charge accumulating film. A stepped portion is disposed at an end of the laminated body. A base layer is formed under the laminated body. The base layer contains silicon and an IV group element different from the silicon.

This application is based on and claims the benefit of priority from prior U.S. prior provisional Patent Application No. 62/153,283, filed on Apr. 27, 2015, the entire contents of which are incorporated herein by reference.

### BACKGROUND

1. Field

Embodiments described herein relate generally to a semiconductor memory device.

2. Description of the Related Art

As one of semiconductor memory devices, there has been provided a flash memory. In particular, since its inexpensiveness and large capacity, a NAND flash memory has been generally widely used. Up to the present, many techniques to further increase the capacity of this NAND flash memory have been proposed. One of the techniques is a structure of three-dimensionally disposing memory cells. In such three-dimensional semiconductor memory devices, the memory cells are disposed in a laminating direction. Conductive layers extend from the respective memory cells, which are disposed in the laminating direction.

### BRIEF DESCRIPTION OF THE DRAWINGS

FIG. 1 is a function block diagram of a semiconductor memory device according to a first embodiment;

FIG. 2 is a schematic perspective view illustrating a configuration of a part of a memory cell array of the semiconductor memory device according to the first embodiment;

FIG. 3 is a schematic diagram illustrating a schematic configuration of a memory cell MC of the semiconductor memory device according to the first embodiment;

FIG. 4 is an equivalent circuit diagram of a memory unit MU of the semiconductor memory device according to the first embodiment;

FIG. 5 is a plan view describing detailed configurations of a memory area MR and a stepped wiring area CR of the semiconductor memory device according to the first embodiment;

FIG. 6A is a cross-sectional view describing detailed configurations of the memory area MR, the stepped wiring area CR, and a peripheral area PA of the semiconductor memory device according to the first embodiment;

FIG. 6B is a plan view describing detailed configurations of the memory area MR, the stepped wiring area CR, and the peripheral area PA of the semiconductor memory device according to the first embodiment;

FIG. 7 is a graph illustrating an effect of the semiconductor memory device according to the first embodiment;

FIG. 8 is a graph illustrating an effect of the semiconductor memory device according to the first embodiment;

FIG. 9 is a graph illustrating an effect of the semiconductor memory device according to the first embodiment;

FIG. 10 to FIG. 19 are process drawings illustrating manufacturing processes of the semiconductor memory device according to the first embodiment;

FIG. 20 is a cross-sectional view describing detailed configurations of the memory area MR, the stepped wiring area CR, and the peripheral area PA of the semiconductor memory device according to a second embodiment;

FIG. 21 to FIG. 23 are process drawings illustrating manufacturing processes of the semiconductor memory device according to the second embodiment;

FIG. 24 is a cross-sectional view describing detailed configurations of the memory area MR, the stepped wiring area CR, and the peripheral area PA of the semiconductor memory device according to the second embodiment; and

FIG. 25 to FIG. 29 are process drawings illustrating manufacturing processes of the semiconductor memory device according to a third embodiment.

### DETAILED DESCRIPTION

According to one embodiment, a semiconductor memory device includes a semiconductor substrate and a laminated body. The semiconductor substrate is made of silicon. The laminated body is disposed on the semiconductor substrate. The laminated body includes a plurality of conductive layers and an interlayer insulating film. The interlayer insulating layer is disposed between the plurality of conductive layers. A memory cell array includes a pillar-shaped semiconductor layer and a memory gate insulating film. A peripheral area of the semiconductor layer is surrounded by the laminated body. The semiconductor layer extends with a first direction as a longitudinal direction. The memory gate insulating film is disposed between the pillar-shaped semiconductor layer and the laminated body. The memory gate insulating film includes an electric charge accumulating film. A stepped portion is disposed at an end of the laminated body. In the stepped portion, positions of an end of a conductive layer at a lower layer and an end of a conductive layer at an upper layer in the first direction differ. A base layer is formed under the laminated body. The base layer contains silicon and an IV group element different from the silicon.

The following describes semiconductor memory devices according to embodiments with reference to the accompanying drawings. Here, these embodiments are only examples. For example, a nonvolatile semiconductor memory device described below has a structure where a memory string extends in a straight line in the vertical direction with respect to a substrate. The similar structure is also applicable to the structure having a U shape where a memory string is folded to the opposite side in the middle. The respective drawings of the nonvolatile semiconductor memory devices used in the following embodiments are schematically illustrated. The thickness, the width, the ratio, and a similar parameter of the layer are not necessarily identical to actual parameters.

The following embodiments relate to a nonvolatile semiconductor memory device in a structure where a plurality of metal-oxide-nitride-oxide-semiconductor (MONOS) type memory cells (transistors) is disposed in a height direction. The MONOS type memory cell includes: a semiconductor film disposed in a columnar shape vertical to the substrate as a channel, and a gate electrode film disposed on the side surface of the semiconductor film via an electric charge accumulating layer. However, a similar structure is also applicable to another type, for example, a semiconductor-oxide-nitride-oxide-semiconductor type (SONOS) memory cell, a metal-aluminum oxide-nitride-oxide-semiconductor type (MANOS) memory cell, a memory cell that uses hafnium oxide (HfOₓ) or tantalum oxide (TaOₓ) as an insulating layer, or a floating-gate type memory cell.

### First Embodiment

First, the following describes an overall configuration of the semiconductor memory device according to the first embodiment.

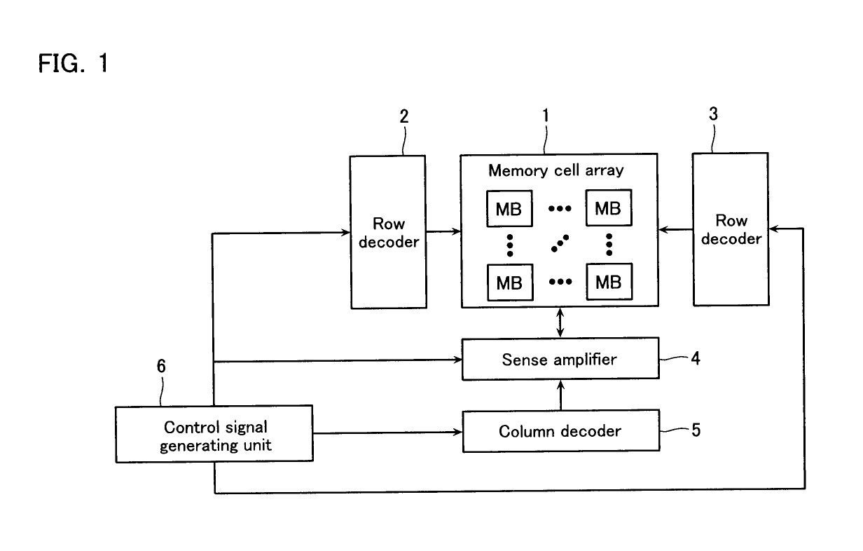

FIG. 1 is a function block diagram of a semiconductor memory device according to the first embodiment. This semiconductor memory device includes a memory cell array 1, row decoders 2 and 3, a sense amplifier 4, a column decoder 5, and a control signal generator 6.

The memory cell array 1 includes a plurality of memory blocks MB. The memory blocks MB each includes a plurality of memory transistors. The memory transistors are a plurality of memory cells MC that are three-dimensionally disposed. The memory block MB is the smallest unit of data erasure operation.

The row decoders 2 and 3 decode retrieved block address signals or similar signals to control a writing operation and a reading operation of data in the memory cell array 1. The sense amplifier 4 detects electric signals flowing through a bit line during the reading operation and amplifies the electric signals. The column decoder 5 decodes column address signals to control the sense amplifier 4. The control signal generator 6 steps up a reference voltage to generate a high voltage used for the writing operation and the erasure operation. Besides, the control signal generator 6 generates control signals to control the row decoders 2 and 3, the sense amplifier 4, and the column decoder 5.

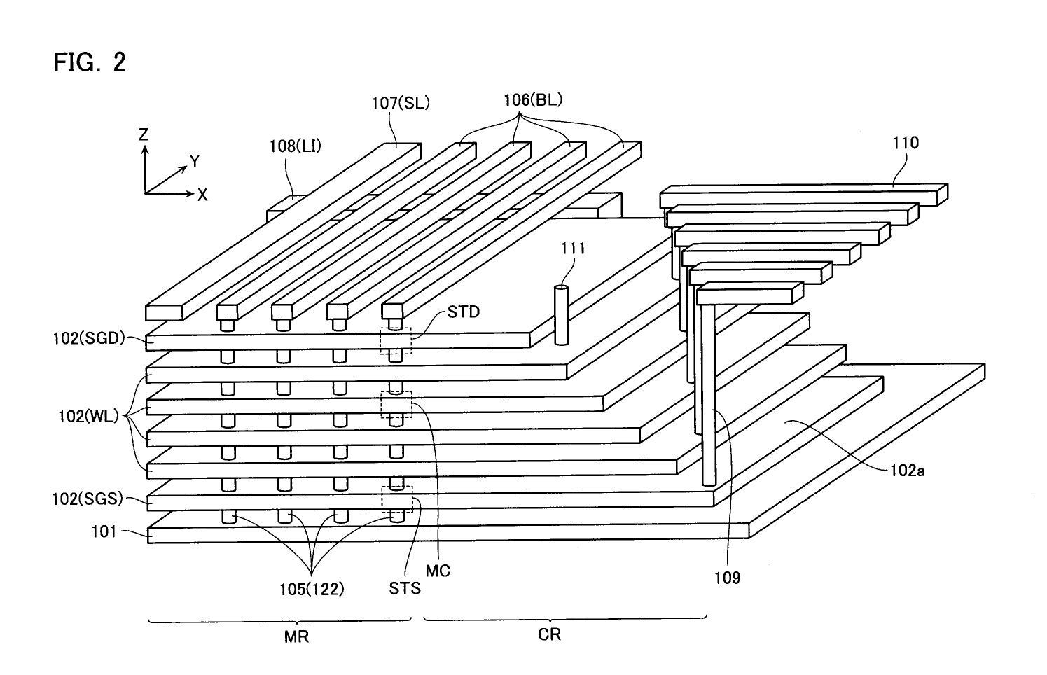

Next, the following describes the schematic configuration of the memory cell array 1 according to the embodiment with reference to FIG. 2. FIG. 2 is a schematic perspective view illustrating the configuration of a part of the memory cell array. FIG. 2 omits illustrations of a part of configurations for simplifying the description. For simplifying the illustration, the count of respective wirings also differs from those of other drawings.

As illustrated in FIG. 2, the memory cell array 1 according to the first embodiment includes a substrate 101 and a plurality of conductive layers 102. The conductive layers 102 are laminated on the substrate 101 in a Z direction. The memory cell array 1 has a plurality of memory columnar bodies 105 extending in the Z direction. As illustrated in FIG. 2, the intersection portions of the conductive layers 102 and the memory columnar bodies 105 function as a source-side selection gate transistor STS, the memory cell MC, or a drain-side selection gate transistor STD. The conductive layer 102 is a conductive layer made of, for example, tungsten (W). The conductive layer 102 functions as a word line WL, a source-side selection gate line SGS, and a drain-side selection gate line SGD. An interlayer insulating layer is formed between the conductive layers 102; however, for simplification, FIG. 2 omits the illustration.

As illustrated in FIG. 2, the plurality of conductive layers 102 at least have wiring portions (stepped portions) formed in a stepped pattern at an end in an X direction. The stepped portion is usually disposed not only at the part in the X direction but also at part in the Y direction; however, the illustration is omitted here. The following refers to an area at which the memory cells MC and a similar component are disposed as a memory area MR. The following refers to a part at which the conductive layers 102 are extracted from this memory area MR to form the conductive layers 102 in the stepped pattern as a stepped wiring area CR.

The conductive layers 102 in the stepped wiring area CR includes contact portions 102a to configure the stepped portions. The contact portion 102a does not face the lower surface of the conductive layer 102 disposed in the upper layer. The conductive layer 102 is coupled to a contact plug 109 at this contact portion 102a. A wiring 110 is disposed at the upper end of the contact plug 109. The contact plug 109 and the wiring 110 are made of the conductive layer such as tungsten.

As illustrated in FIG. 2, the memory cell array 1 according to the first embodiment includes a support pillar 111. The support pillar 111 is disposed so as to have a longitudinal direction in a laminating direction of a laminated body formed of the plurality of conductive layers 102 and the interlayer insulating layers between the conductive layers 102. This support pillar 111 is formed to maintain the shape of the laminated body during the manufacturing process for this laminated body. The conductive layers 102 may be formed by the following processes as described later. The interlayer insulating layers and sacrificial layers are laminated. Then, the sacrificial layers are removed by wet etching or a similar method. Afterward, the conductive films are embedded into voids formed by removing the sacrificial layers. When performing such processes, to prevent the interlayer insulating layer from collapsing, the above-described support pillar 111 is disposed. FIG. 2 representatively illustrates only one support pillar 111. However, the actual device may include more of the support pillars 111.

As illustrated in FIG. 2, the memory cell array 1 according to the first embodiment includes a conductive layer 108. The conductive layer 108 opposes the side surfaces of the plurality of conductive layers 102 in the Y direction and extends in the X direction. The lower surface of the conductive layer 108 is in contact with the substrate 101. The conductive layer 108 is a conductive layer made of, for example, tungsten (W). The conductive layer 108 functions as a source contact LI.

The material of the conductive layer 102, as well as the above-described tungsten (W), is possibly constituted of a conductive layer such as WN, Al, Ti, V, Cr, Mn, Fe, Co, Ni, Cu, TiN, WSiₓ, TaSiₓ, PdSiₓ, ErSiₓ, YSiₓ, PtSiₓ, HfSiₓ, NiSiₓ, CoSiₓ, TiSiₓ, VSiₓ, CrSiₓ, MnSiₓ, and FeSiₓ.

As illustrated in FIG. 2, the memory cell array 1 according to the first embodiment includes a plurality of conductive layers 106 and a conductive layer 107. The plurality of conductive layers 106 and the conductive layer 107 disposed above the plurality of conductive layers 102 and memory columnar bodies 105. The plurality of conductive layers 106 are disposed in the X direction. The plurality of conductive layers 106 and the conductive layers 107 extend in the Y direction. The memory columnar bodies 105 are each coupled to the lower surfaces of the conductive layers 106. The conductive layer 106 is, for example, constituted of the conductive layer such as tungsten (W) and functions as a bit line BL. The conductive layer 108 is coupled to the lower surfaces of the conductive layers 107. The conductive layer 107 is, for example, constituted of the conductive layer such as tungsten (W) and functions as a source line SL. The top surface of the conductive layer 108 is coupled to the conductive layer 107 (the source line SL). Meanwhile, as described later, the lower surface of the conductive layer 108 is coupled to the semiconductor substrate. Thus, the conductive layer 108 functions as the source contact LI to electrically couple the source line SL and the memory columnar body 105.

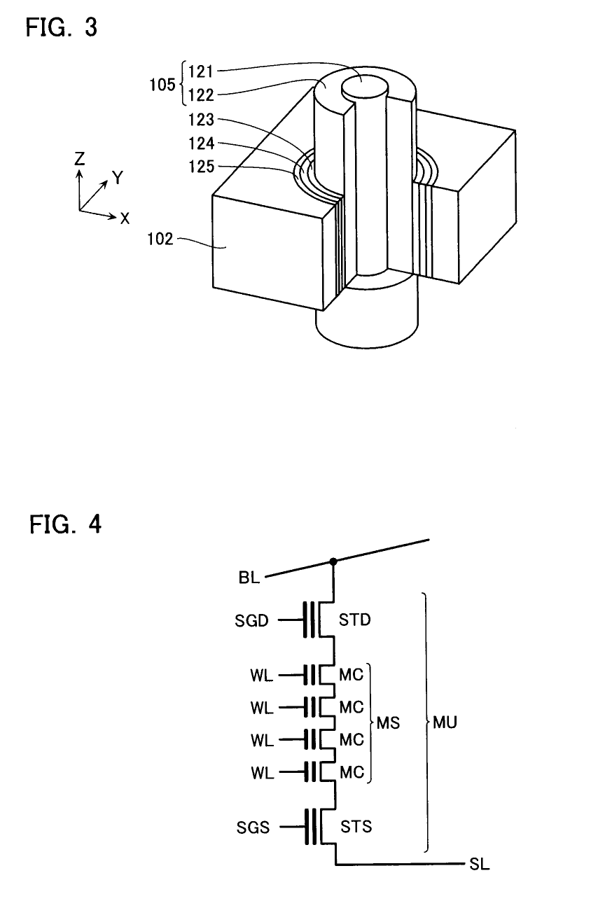

Next, with reference to FIG. 3, the following describes the schematic configuration of the memory cell MC according to the first embodiment. FIG. 3 is a schematic perspective view illustrating the configuration of the memory cell MC. FIG. 3 illustrates the configuration of the memory cell MC. Note that the source-side selection transistor STS and the drain-side selection transistor STD may also be configured similar to the memory cell MC. FIG. 3 omits a part of the configuration.

As illustrated in FIG. 3, the memory cell MC is disposed at a portion where the conductive layer 102 intersects with the memory columnar body 105. The memory columnar body 105 includes a core insulating layer 121 and a columnar semiconductor layer 122. The semiconductor layer 122 covers the sidewall of the core insulating layer 121. Moreover, between the semiconductor layer 122 and the conductive layer 102, a memory gate insulating film is disposed. The memory gate insulating film includes a tunnel insulating layer 123, an electric charge accumulating layer 124, and a block insulating layer 125. The core insulating layer 121 is constituted of, for example, an insulating layer such as silicon oxide (SiO₂). The semiconductor layer 122 is constituted of, for example, a semiconductor layer such as polysilicon. The semiconductor layer 122 functions as a channel for the memory cell MC, the source-side selection transistor STS, and the drain-side selection gate transistor STD. The tunnel insulating layer 123 is constituted of, for example, an insulating layer such as silicon oxide (SiO₂). The electric charge accumulating layer 124 is constituted of, for example, an insulating layer such as silicon nitride (SiN) that can accumulate electric charges. The block insulating layer 125 is constituted of, for example, an insulating layer such as silicon oxide (SiO₂).

The material of the semiconductor layer 122, as well as the above-described polysilicon, is possibly constituted of a semiconductor such as SiGe, SiC, Ge, and C. Surfaces at which the semiconductor layer 122 is in contact with the substrate 101 and the conductive layers 106, silicide may be formed. As such silicide, for example, Sc, Ti, VCr, Mn, Fe, Co, Ni, Cu, Zn, Rh, Pd, Ag, Cd, In, Sn, La, Hf, Ta, W, Re, Os, Ir, Pt, and Au may be used. Additionally, Sc, Ti, VCr, Mn, Fe, Co, Ni, Cu, Y, Zr, Nb, Mo, Tc, Ru, Rh, Pd, Ag, Cd, In, Sn, La, Hf, Ta, W, Re, Os, Ir, Pt, Au, or a similar material may be added to the silicide thus formed.

The tunnel insulating layer 123 and the block insulating layer 125 are possibly formed of a material such as oxide and oxynitride, in addition to the above-described silicon oxide (SiO₂). The oxide constituting the tunnel insulating layer 123 and the block insulating layer 125 is possibly SiO₂, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, AlSiO, or a similar material. The oxide constituting the tunnel insulating layer 123 and the block insulating layer 125 may be AB₂O₄. Note that A and B described here are identical or different elements and one of elements among Al, Sc, Ti, V, Cr, Mn, Fe, Co, Ni, Cu, Zn, Ga, and Ge. For example, AB₂O₄ is Fe₃O₄, FeAl₂O₄, Mn₁₊ₓAl₂₋ₓO_{4+y}, Co₁₊ₓAl₂₋ₓO_{4+y}, MnOₓ or a similar material.

The oxide constituting the tunnel insulating layer 123 and the block insulating layer 125 may be ABO₃. Note that A and B described here are identical or different elements and one of elements among Al, La, Hf, Ta, W, Re, Os, Ir, Pt, Au, Hg, Ti, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn. For example, ABO₃ is, LaAlO₃, SrHfO₃, SrZrO₃, SrTiO₃, or a similar material.

The oxynitride constituting the tunnel insulating layer 123 and the block insulating layer 125 is possibly, for example, SiON, AlON, YON, LaON, GdON, CeON, TaON, HfON, ZrON, TiON, LaAlON, SrHfON, SrZrON, SrTiON, HfSiON, HfAlON, ZrSiON, ZrAlON, and AlSiON.

The oxynitride constituting the tunnel insulating layer 123 and the block insulating layer 125 may be a material constituted by replacing some of oxygen elements of the respective materials described above as an oxide constituting the tunnel insulating layer 123 and the block insulating layer 125 with a nitrogen element.

As the material for the tunnel insulating layer 123 and the block insulating layer 125, SiO₂, SiN, Si₃N₄, Al₂O₃, SiON, HfO₂, HfSiON, Ta₂O₅, TiO₂, or SrTiO₃ is preferable.

In particular, an Si-based insulating film such as SiO₂, SiN, and SiON includes an insulating film whose respective concentrations of the oxygen element and the nitrogen element are 1×10¹⁸ atoms/cm³ or more. Note that a barrier height of the plurality of insulating layers differ from one another.

The tunnel insulating layer 123 and the block insulating layer 125 may contain impurity atoms forming defective levels or semiconductor/metal dot (a quantum dot).

The coupling of the memory cell MC and the selection transistors STD and STS with the above-described configuration in series configures a memory unit MU as illustrated in FIG. 4. That is, the memory unit MU includes a memory string MS, the source-side selection transistor STS, and the drain selection transistor STD. The memory string MS is formed of the plurality of memory cells MC coupled in series. The source-side selection transistor STS and the drain selection transistor STD are coupled to both ends of the memory string MS. Some of the plurality of memory cells MC in the memory string MS can be dummy cells not used for data storage. The count of dummy cells may be set to any given count.

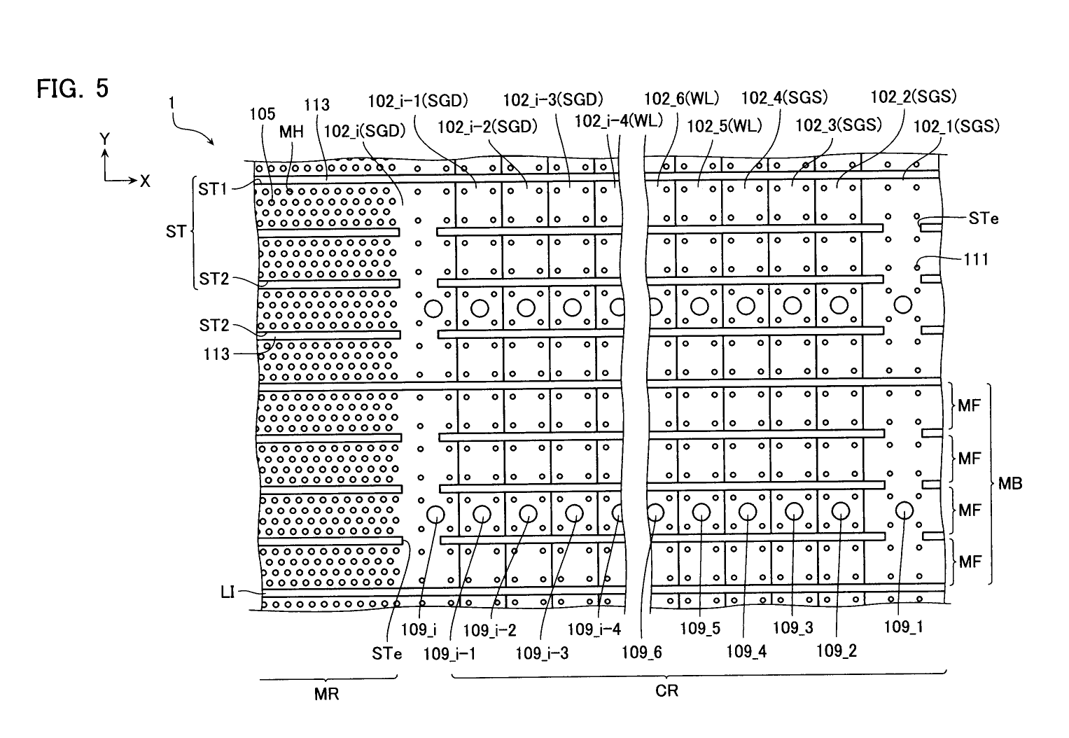

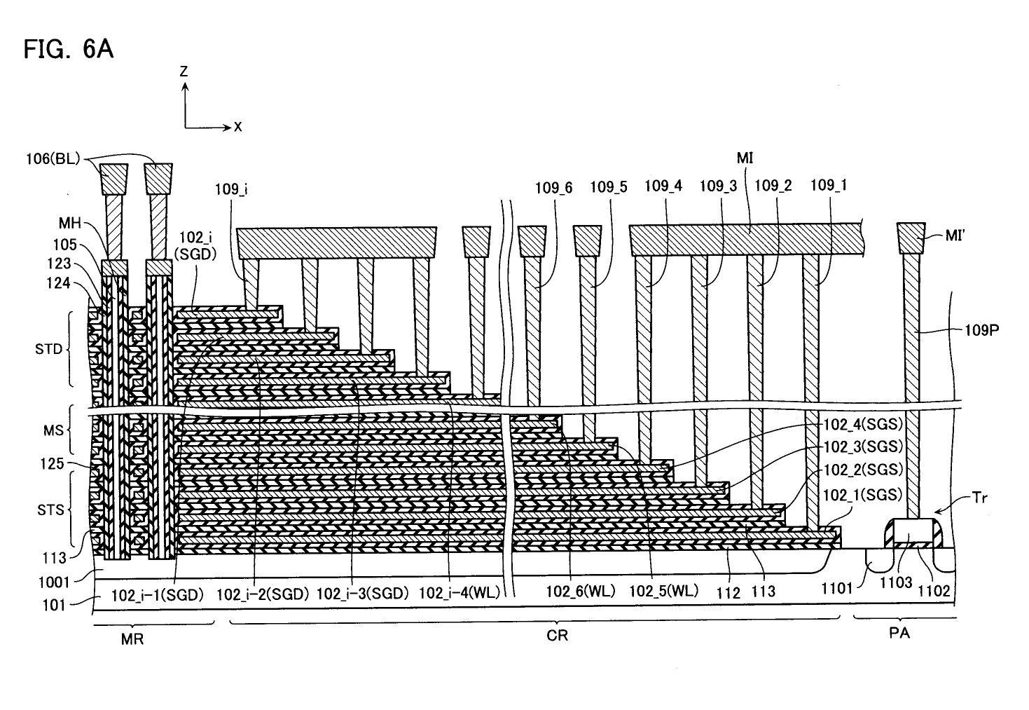

Next, with reference to FIG. 5 to FIG. 6B, the following describes details of the configuration of the memory area MR and the stepped wiring area CR of the semiconductor memory device according to the first embodiment. FIG. 5 is a plan view illustrating the configurations of the memory area MR and the stepped wiring area CR. FIG. 6A is a cross-sectional view of the memory area MR and the stepped wiring area CR along the XZ plane in FIG. 5. FIG. 6A also illustrates a cross-sectional view of a peripheral area PA. FIG. 6B is a plan view of the memory area MR and the stepped wiring area CR. FIG. 5 and FIG. 6A differ from the count of word lines WL and the selection gate lines SGD and SGS from those of the schematic diagram in FIG. 2.

As illustrated in FIG. 5, the memory cell array 1 according to the first embodiment includes the memory area MR and the stepped wiring area CR. The memory unit MU is formed at the memory area MR. The stepped wiring area CR extends from the memory area MR.

As illustrated in FIG. 6A, in the memory area MR, a plurality of (i pieces) of the conductive layers 102 (102_1 to 102_i) are laminated on the substrate 101 sandwiching the interlayer insulating films 112 and 113.

A large count of memory holes MH are formed in the memory area MR so as to pass through the laminated body of these conductive layers 102 and interlayer insulating films 112 and 113. In this memory hole MH, the above-described memory columnar body 105 is formed via the tunnel insulating layer 123 and the electric charge accumulating layer 124 (see FIG. 6A). That is, the memory columnar body 105 is formed such that the peripheral area of the memory columnar body 105 is surrounded by the laminated body of the conductive layer 102 and the interlayer insulating films 112 and 113.

As illustrated in FIG. 6A, the block insulating layers 125 are formed not the inside of the memory holes MH but so as to cover the peripheral areas of the conductive layers 102_1 to 102_i. The upper end of the memory columnar body 105 is coupled to the above-described conductive layer 106 (the bit line BL) via a contact wiring or a similar wiring.

In the example illustrated in FIG. 5, the memory holes MH are disposed in a houndstooth pattern in the XY plane. The disposition of the memory holes MH in the XY direction can be appropriately adjusted into a triangular disposition, a square disposition, or a similar disposition.

As illustrated in FIG. 5, a large count of the above-described support pillars 111 are formed at the stepped wiring area CR. Contact plugs 109 (109_1 to 109_i) are coupled to the exposed portions of the respective conductive layers 102 constituting the stepped wiring area CR. The upper ends of the contact plug 109 are coupled to upper layer wirings M1. Through such upper layer wirings M1 and wiring layers (not illustrated), the contact plug 109 is coupled to an external circuit. This upper layer wiring M1 functions as the wiring 110 in FIG. 2.

As illustrated in FIG. 6A, with the first embodiment, the conductive layers 102_1 to 102_4 function as the source-side selection gate line SGS and the control gates electrodes of the source-side selection gate transistor STS. That is, in the structure illustrated in FIG. 6A, the four source-side selection gate lines SGS are coupled to one source-side selection transistor STS.

The conductive layers 102_5 to 102_i−4 function as the word lines WL and the control gate electrodes of the memory cells MC. That is, in the structure illustrated in FIG. 6A, one memory string MS includes (i−8) pieces of the memory cells MC. (i−8) pieces of the word lines WL are coupled to the memory cells MC.

The conductive layers 102_i−3 to 102_i function as control gate electrodes for the drain-side selection gate line SGD and the drain-side selection gate transistor STD. That is, in the structure illustrated in FIG. 6A, the four drain-side selection gate lines SGD are coupled to one drain-side selection transistor STD.

The counts of the source-side selection gate lines SGS and the drain-side selection gate lines SGD formed in one memory unit MU (the memory columnar body 105) are not limited to four as illustrated in the drawing, but may be another count or can be only one.

The stepped wiring area CR has a structure of forming the above-described conductive layers 102 and interlayer insulating films 112 in a stepped pattern. That is, the top surface of the end of the conductive layer 102_k, which is a lower layer, is not covered with the conductive layer 102_k+1, which is the upper layer. As the conductive layer 102 is disposed at the lower layer, the end position is disposed remotely from the memory area MR. As a result of providing such stepped pattern structure, the conductive layers 102 each has the exposed part not covered with the conductive layer upper than this layer. This exposed part can be coupled to the contact plug 109. The upper end of the contact plug 109 is coupled to the upper layer wiring M1.

As illustrated in FIG. 5, a large count of slits ST (ST1 and ST2) with the longitudinal direction in the X direction are formed at the memory area MR and the stepped wiring area CR. An isolation insulating film is embedded or the above-described source contact LI is embedded into the slit ST via the isolation insulating film. That is, the isolation insulating film is embedded into the slit ST. Thus, the isolation insulating film has a role to electrically insulate and separate the conductive layers 102 positioned at both sides. When forming the conductive layer 102, this slit ST is formed to remove the sacrificial layer, which will be described later, by etching.

As illustrated in FIG. 5, the slit ST extends with the X direction as the longitudinal direction. Additionally, the slit ST is formed so as to separate the laminated body of the conductive layers 102 and the interlayer insulating layers from the surface to the bottom. Thus, the slit ST separates the conductive layers 102_2 to 102_i in the memory area MR and the stepped wiring area CR in the Y direction. The slits ST has two types of slits ST1 and ST2. All the slits ST1 and ST2 are formed to extend from the surface of the conductive layer 102_i to the substrate 101. This slit ST1 divides the memory area MR and the stepped wiring area CR into the plurality of memory blocks MB. Furthermore, the slit ST2 divides one memory block MB into a plurality of memory fingers MF.

The slit ST1 is a slit formed between the two memory blocks MB. The slit ST2 is a slit formed between the two memory fingers MF in one memory block MB. The slit ST1 separates the two memory blocks MB up to the conductive layer 102_1, which is the lowest layer. Meanwhile, the slit ST2 has a terminating end portion STe at any position in the stepped wiring area CR. In the example illustrated in FIG. 5, the terminating end portions STe are formed at the conductive layer 102_i, which is the uppermost layer and at the conductive layer 102_1, which is the lowermost layer. The slits ST2 are continuously formed opposed to one another sandwiching the terminating end portion in the X direction. In view of this, the slit ST2 does not electrically separate the conductive layers 102 in the adjacent memory fingers MF. The adjacent memory fingers MF are electrically coupled to one another at the parts of the terminating end portions STe (More specifically, at the position between the two terminating end portions STe disposed alongside in the X direction, the conductive layer 102 disposed at a first side, which is the Y direction viewed from the slit ST2, and the conductive layer 102 disposed at a second side, which is the Y direction viewed from the slit ST2 are electrically coupled).

Thus, the slit ST2 includes the terminating end portion STe to keep the plurality of memory fingers MF included in one memory block MB coupled, not electrically separating the memory fingers MF, and to minimize the count of the required contact plugs. It is needless to say that the positions at which the terminating end portions STe are formed are not limited to the example illustrated in the drawing. For example, the terminating end portion STe can also be formed only at the conductive layer 102_i, which is the lowermost layer.

A transistor Tr is formed on the semiconductor substrate 101 in the peripheral area PA. The transistor Tr configures the peripheral circuit. As illustrated in FIG. 6A, the transistor Tr includes a source/drain diffusion area 1101 and a gate electrode 1103. The source/drain diffusion area 1101 is formed on the surface of the semiconductor substrate 101. The gate electrode 1103 is formed on the surface of the semiconductor substrate 101 between the source/drain diffusion areas 1101 via a gate insulating film 1102. A contact plug 109P is coupled to the surface of this gate electrode 1103. A metal wiring MI′ is coupled to the upper end of the contact plug 109P.

With this embodiment, a silicon germanium layer 1001 (a base layer) is formed at a surface of the semiconductor substrate 101 (namely, at the memory area MR and the stepped wiring area CR) below the laminated body of the conductive layers 102 and the interlayer insulating films 112 and 113. This silicon germanium layer 1001 is formed by implanting germanium, which is an exemplary IV group element different from silicon, on the semiconductor substrate 101 whose material is silicon. This silicon germanium layer 1001 of the first embodiment is formed below the surface of the semiconductor substrate 101. This silicon germanium layer 1001 is the base layer formed lower than the above-described laminated body. A lattice mismatch between the silicon and the germanium generates compressive stress. This plays a role of offsetting the tensile stress generated in another layer and preventing the substrate 101 from warping. The following describes this role in detail.

As a metallic material constituting the above-described conductive layer 102 and source contact LI, a high melting point metal such as tungsten may be used. The following exemplifies tungsten an exemplary high melting point metal; however, it is needless to say that it is not limited to tungsten. When a tungsten film shrinks after the film formation, the tungsten film internally generates the tensile stress around several GPa. This possibly generates a warp in the substrate 101. In a manufacturing process subsequent to the film formation process of tungsten, the warp of such substrate 101, for example, possibly makes it difficult to convey the substrate 101 by a conveying device or possibly causes a displacement in matching the pattern in a lithography process. Meanwhile, the nonvolatile semiconductor memory device with three-dimensional structure like this embodiment has been requested to increase the count of laminated word lines from the aspect of improving a degree of integration. The increase in the count of laminated word lines further increases the above-described tensile stress, making the problem of warp of the substrate more serious. This possibly makes the production of such three-dimensional nonvolatile semiconductor memory device at a stable yield difficult.

Therefore, the embodiment includes the above-described silicon germanium layer 1001 on the semiconductor substrate 101. This silicon germanium layer 1001 provides the compressive stress to the substrate 101 inversely with the tensile stress provided by the tungsten layer. Since this compressive stress by the silicon germanium layer 1001 and the tensile stress by the tungsten layer are offset, the warp of the substrate 101 may be restricted. The silicon germanium layer 1001 is to offset the tensile stress by the conductive layer 102 included in the laminated body formed in the memory area MR and the stepped wiring area CR. Accordingly, as illustrated in FIG. 6B, the silicon germanium layer 1001 is mainly formed in the memory area MR and the stepped wiring area CR. The silicon germanium layer 1001 is not formed in the area not including the laminated body, for example, the peripheral area PA. The silicon germanium layer 1001 of this embodiment is formed to have a shape substantially same as the planar shape of the conductive layers 102 formed in the memory area MR and the stepped wiring area CR.

Changing a germanium concentration in the silicon germanium layer 1001 ensures changing the value of the provided compressive stress.

The silicon germanium layer 1001 of the embodiment is preferably formed at a part substantially matching a part below the area where the laminated body in which the plurality of conductive layers 102 containing tungsten are formed (specifically, in the memory area MR and the stepped wiring area CR) is formed. However, needless to say, it is also possible that the formation regions of both differ within a range of ensuring restraining the warp of the substrate.

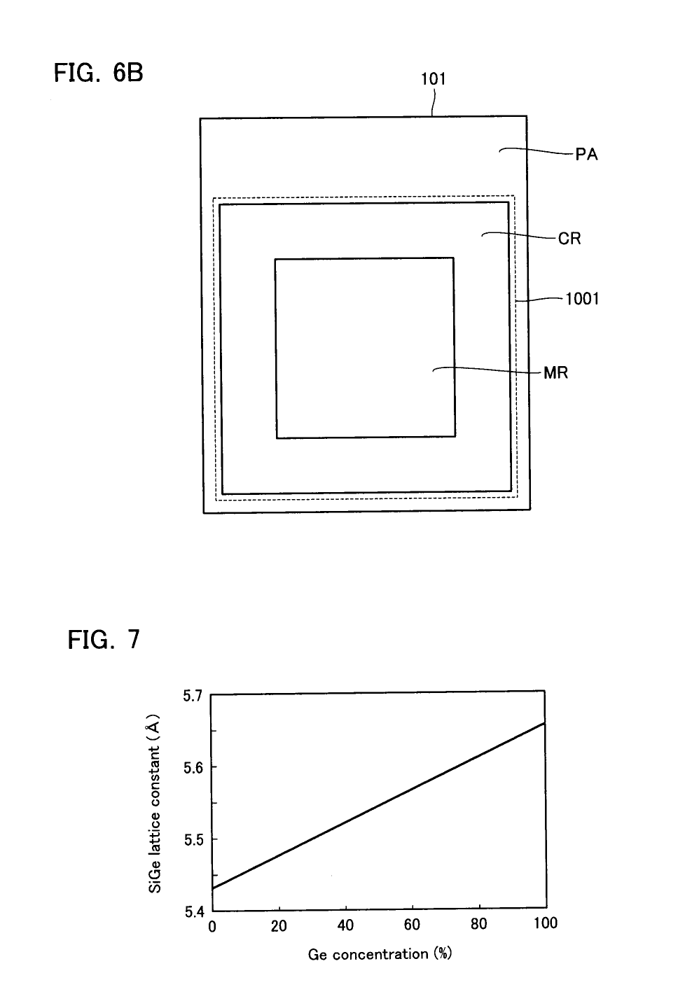

FIG. 7 is a graph illustrating the relationship between the concentration of the germanium in the silicon germanium layer 1001 and a lattice constant of SiGe in the silicon germanium layer 1001. The lattice constant of silicon is 5.431 A while the lattice constant of germanium is 5.656 A. The lattice mismatch percentage is 4.1%. The change in the concentration of germanium in the silicon germanium layer 1001 within the range of 0 to 100% changes the lattice constant of the silicon germanium layer 1001 within the range of 5.431 to 5.656.

FIG. 8 is a graph illustrating the relationship between the germanium concentration in the silicon germanium layer 1001, the film thickness of the silicon germanium layer 1001, and the amount of warp of the substrate 101. As illustrated in FIG. 8, the larger the concentration of germanium, the larger the compressive stress provided by the silicon germanium layer 1001 is. Accordingly, the amount of warp of the substrate 101 increases by the amount. The larger the film thickness of the silicon germanium layer 1001, the larger the amount of warp of the substrate 101 is by the amount.

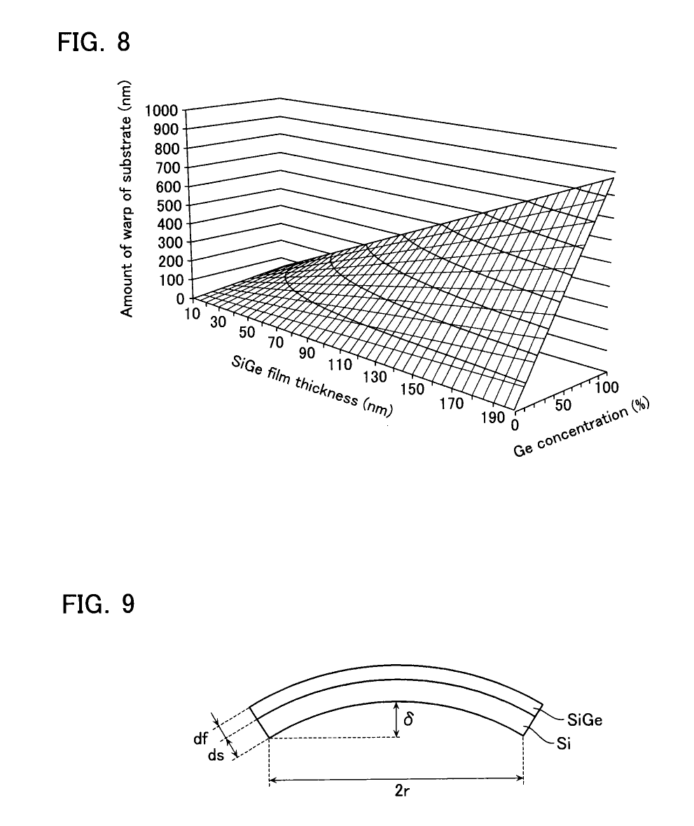

With reference to FIG. 9, the following describes the relationship between various factors and the warp of this laminated structure (displacement δ) in the structure where a silicon layer at a thickness ds and the silicon germanium layer at a thickness df are laminated. Assume the case where the coverage factor of the germanium layer to the silicon layer is 100%. In the case where the Poisson's ratio of the silicon layer is referred to as v, the Young's modulus of the silicon layer as Es, the compressive stress provided by the germanium layer as σ, and a length of a chord of the displaced part as 2r, the displacement δ is expressed by the following formula. By selecting the df, ds, v, and σ values to offset this displacement δ and the displacement provided by the tungsten layer, the warp of the substrate 101 can be appropriately restrained. The following δ value is set such that the warp of the substrate 101 after forming the conductive layer 102 preferably becomes ±150 μm or less, and further preferably becomes ±100 μm or less.

δ={σr²3(1−v)/Es}(df/ds²) [Expression 1]

In the case where the coverage factor of the germanium layer to the silicon layer is less than 100%, the displacement δ is calculated as a value found by multiplying the right side of the above-described equation by a variable based on the coverage factor.

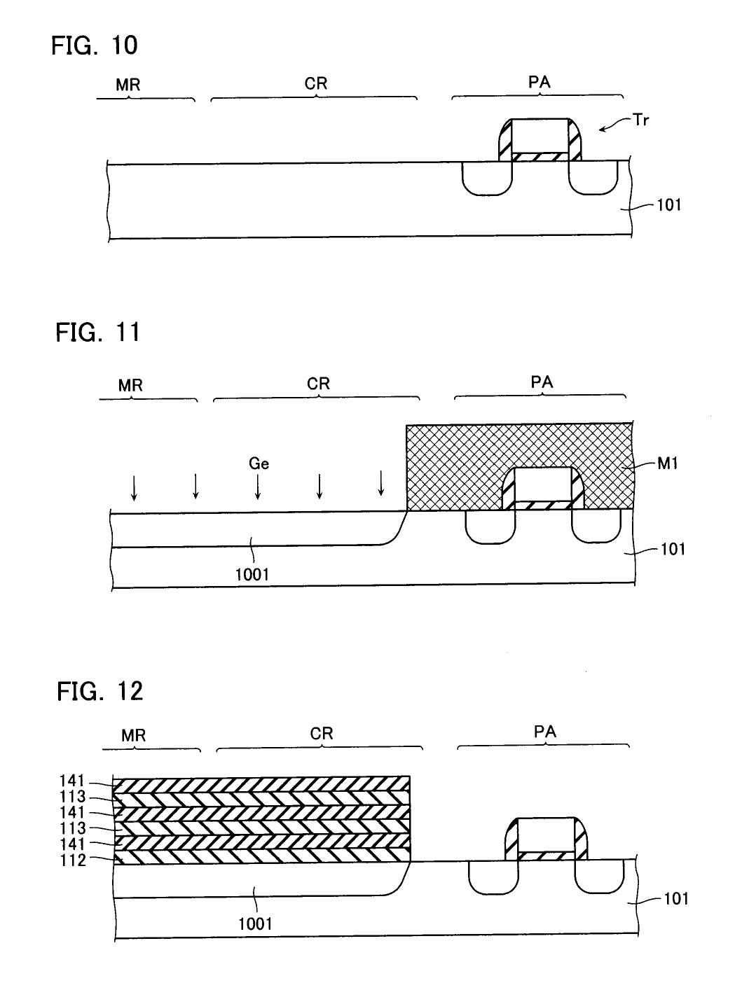

Next, the following describes a method for forming this silicon germanium layer 1001 with reference to FIG. 10 to FIG. 12.

As illustrated in FIG. 10, among the memory area MR, the stepped wiring area CR, and the peripheral area PA, the above-described transistor Tr is formed in the peripheral area PA by the well-known method. Thereafter, as illustrated in FIG. 11, after covering the peripheral area PA with a resist M1, germanium ion is implanted to the memory area MR and the stepped wiring area CR not covered with the resist M1, and subsequently a thermal process is performed. This diffuses the germanium ion on the surface of the silicon substrate 101, thus forming the silicon germanium layer 1001. The dose amount of germanium, an accelerating voltage during the implantation, or a similar parameter is adjusted in accordance with the required germanium concentration of the silicon germanium layer 1001 and the required film thickness of the silicon germanium layer 1001. Instead of the ion implantation, the silicon germanium layer 1001 can also be formed by plasma doping.

After forming this silicon germanium layer 1001, as illustrated in FIG. 12, formation of members configuring the memory cell array on the top surfaces of the memory area MR and the stepped wiring area CR is started.

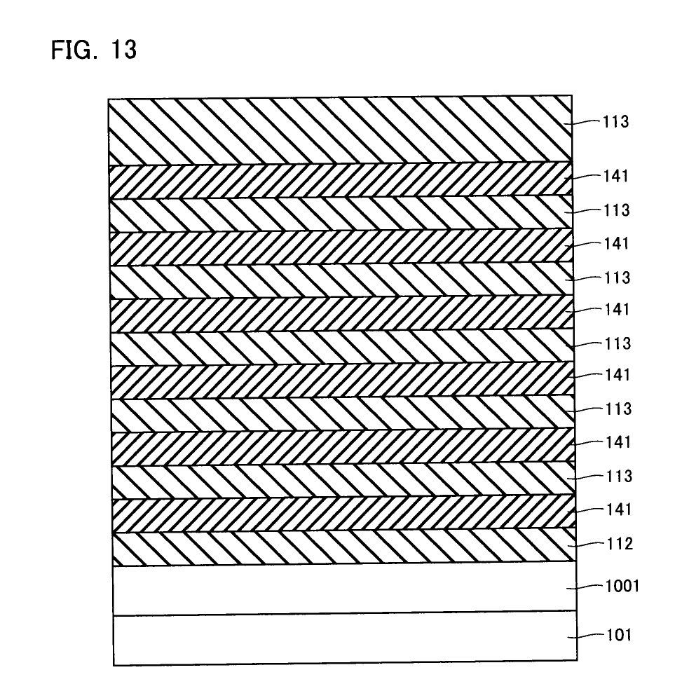

With reference to FIG. 13 to FIG. 19, the following describes a method for manufacturing the memory cell array in the memory area MR.

As illustrated in FIG. 13, the interlayer insulating films 112 and 113 are laminated sandwiching a sacrificial layer 141 between them above the semiconductor substrate 101. When forming the interlayer insulating films 112 and 113 with silicon oxide film, the sacrificial layer 141 may be formed of silicon nitride film (SiN). This sacrificial layer 141 is deposited using the CVD method or a similar method. It is preferable to adjust a film forming condition at that time to provide the tensile stress by the sacrificial layer 141. This offsets the tensile stress by the sacrificial layer 141 and the compressive stress by the silicon germanium layer 1001, ensuring restraining the warp of the substrate 101.

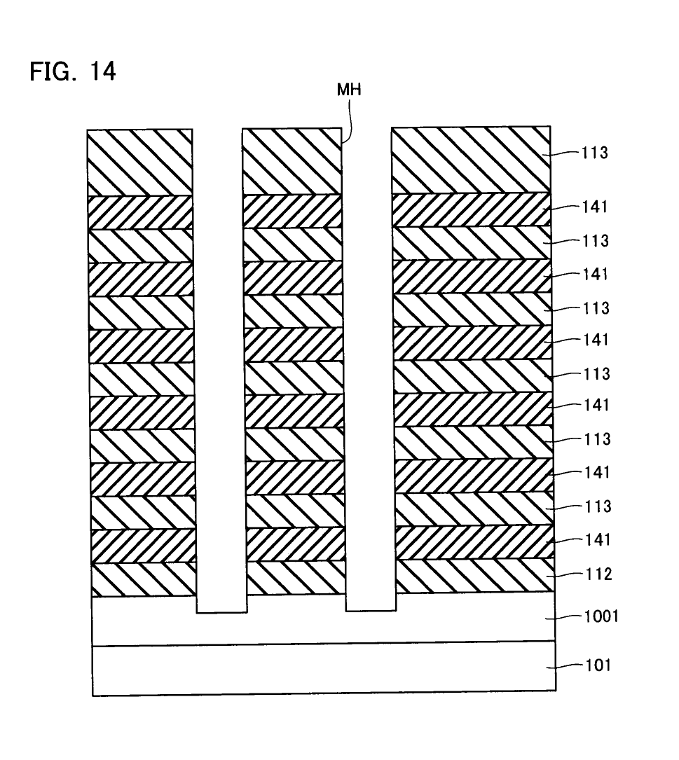

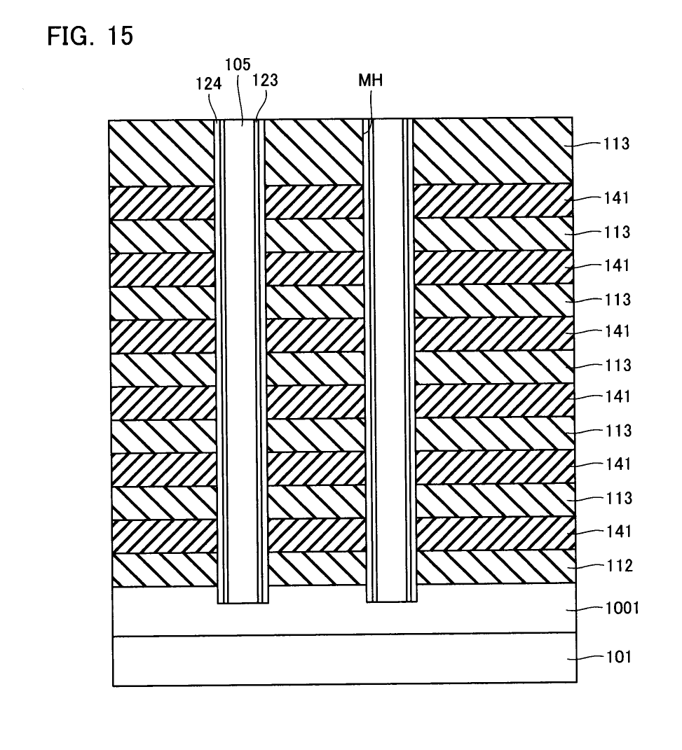

Subsequently, as illustrated in FIG. 14, the memory holes MH passing through the interlayer insulating films 112 and 113 and the sacrificial layers 141 are formed. Next, as illustrated in FIG. 15, the CVD method is performed to sequentially form the electric charge accumulating layers 124, the tunnel insulating layers 123, and the memory columnar bodies 105 in the memory holes MH, thus forming the memory units MU.

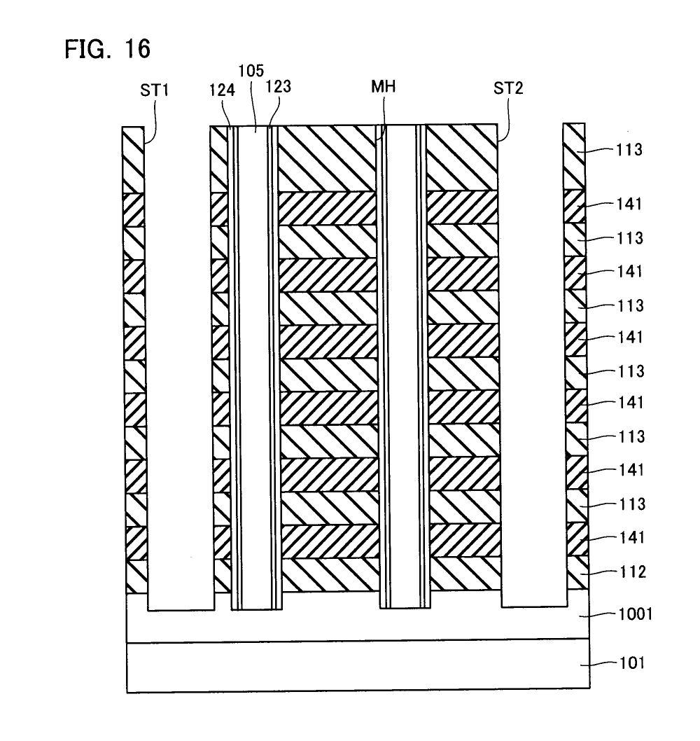

As illustrated in FIG. 16, after forming the memory columnar bodies 105 or a similar member, RIE is performed to form the slits ST1 and ST2 passing through the interlayer insulating films 112 and 113 and the sacrificial layers 141.

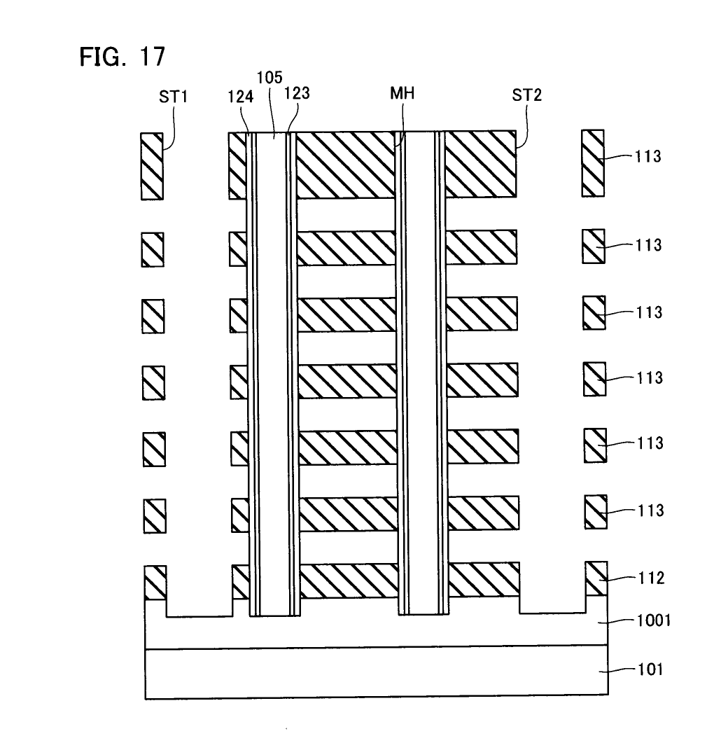

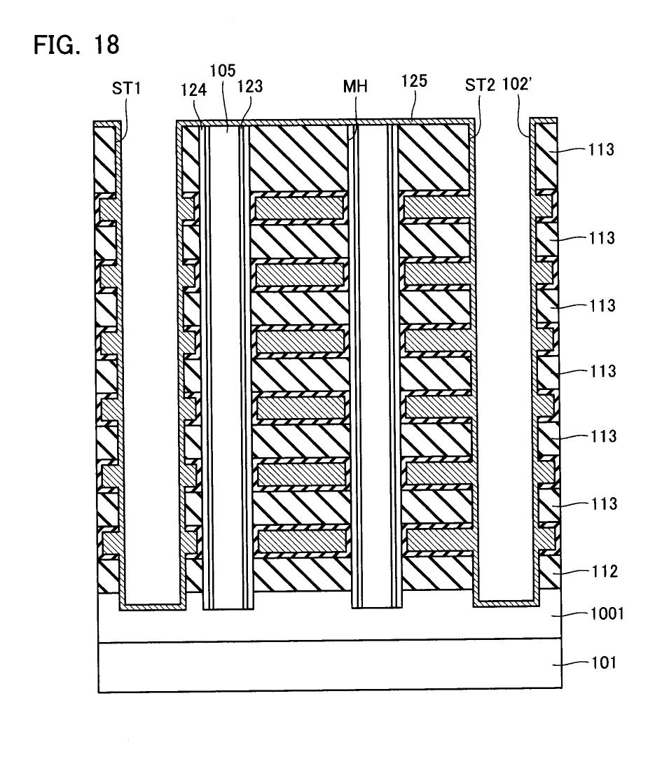

Next, as illustrated in FIG. 17, by the wet etching using a hot phosphoric acid solution via the slits ST1 and ST2, the sacrificial layers 141 are removed. As illustrated in FIG. 18, conductive films 102′ formed of tungsten are deposited to the voids left after removing the sacrificial layers 141 via the block insulating layer 125 by the CVD method. The deposited conductive films 102′ are deposited to project from the inner walls of the slits ST1 and ST2 to the centers of the slits ST1 and ST2.

The tungsten, which is the material of this conductive film 102′, provides the tensile stress. However, the compressive stress from the silicon germanium layer 1001, which is present below the conductive film 102′, offsets the tensile stress, restraining the warp of the substrate 101.

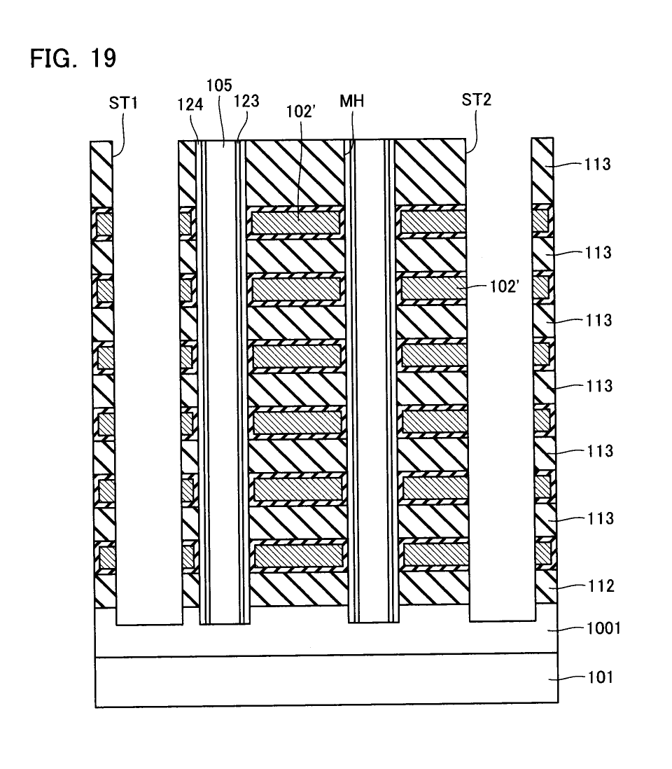

If such conductive films 102′, which project from the inner walls of the slits ST1 and ST2 to the center are left, the conductive film 102′, which is opposed to the conductive film 102′ sandwiching the interlayer insulating layer in the laminating direction, shorts, failing to obtain the desired operation. Accordingly, as illustrated in FIG. 19, the wet etching is further performed to etch-back the conductive film 102′. This prevents the conductive films 102′ adjacent in the laminating direction from shorting.

Although the illustration is omitted, in the slit ST1, the source contact LI is formed by the well-known method, and the interlayer insulating layer is embedded into the slit ST2. At the stepped wiring area CR, while gradually etch-backing the resist formed on the top surface of the above-described laminated body, the wet-etching is performed. This forms the stepped portion illustrated in FIG. 6A at the stepped wiring area CR.

As described above, according to the semiconductor memory device of the embodiment, even if the conductive film made of, for example, tungsten, which provides the tensile stress, is formed as the conductive layer 102, by the compressive stress provided by the silicon germanium layer 1001, the tensile stress and the compressive stress can be offset. This allows restraining the warping generated in the substrate 101.

### Second Embodiment

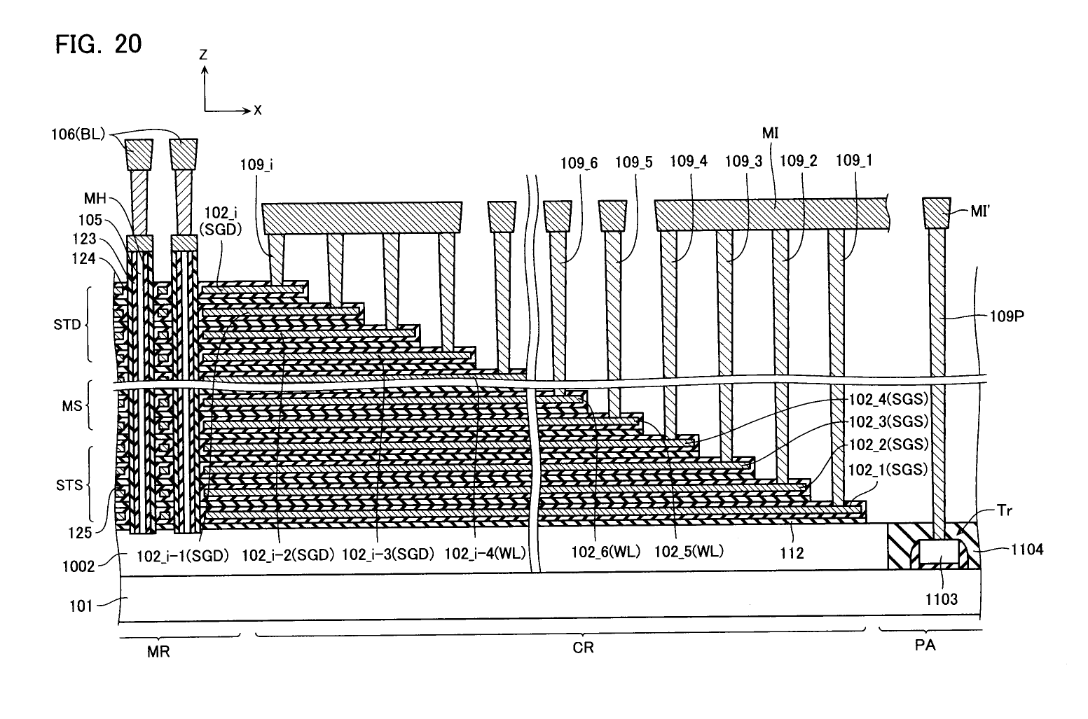

Next, the following describes a semiconductor memory device according to the second embodiment with reference to FIG. 20. In this second embodiment, the overall structure of the semiconductor memory device is similar to that of the first embodiment (in FIG. 1 to FIG. 5). Therefore, the overlapped description will not be further elaborated here. Note that this second embodiment differs from the first embodiment in the structure of the silicon germanium layer disposed below the conductive layer 102.

As illustrated in FIG. 20, this second embodiment includes a silicon germanium layer 1002. The silicon germanium layer 1002 is deposited on the surface of the substrate 101 by a film forming method such as an epitaxial growth, the CVD method, and the PVD method. This silicon germanium layer 1002 is deposited at the side of an interlayer insulating film 1004 in the peripheral area PA. Into the interlayer insulating film 1004, the gate electrode 1103 of the transistor Tr is embedded. In this respect, the silicon germanium layer 1002 differs from the silicon germanium layer 1001 of the first embodiment in that the silicon germanium layer 1001 is formed on the surface of the semiconductor substrate 101 by the ion implantation and the plasma doping. In other words, the silicon germanium layer 1001 of the first embodiment is formed below the surface of the semiconductor substrate 101. Meanwhile, this silicon germanium layer 1002 of the second embodiment is formed above the surface of the semiconductor substrate 101.

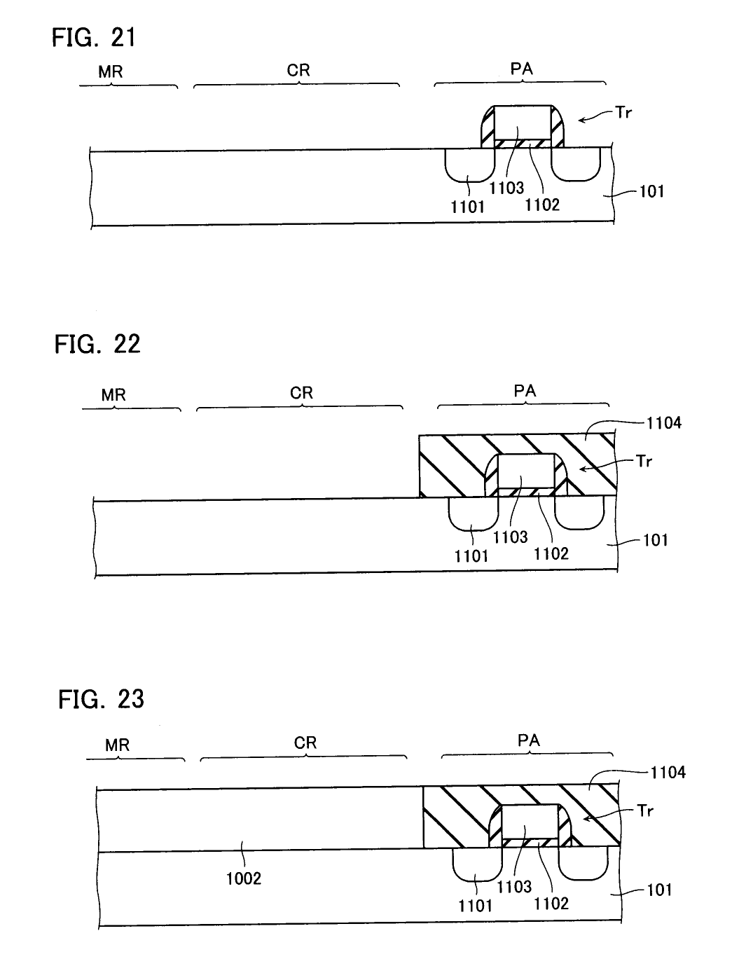

Next, the following describes the method for manufacturing this semiconductor memory device of the second embodiment with reference to FIG. 21 to FIG. 23. The manufacturing process for the memory cell array 1 is similar to that of the first embodiment. Accordingly, the following omits the description. The following describes only a procedure for forming the silicon germanium layer 1002.

First, as illustrated in FIG. 21, after forming the transistor Tr at the peripheral area PA, as illustrated in FIG. 22, an interlayer insulating film 1104 in which the gate electrode 1103 of this transistor Tr or a similar member is to be embedded is formed on the semiconductor substrate 101 at the peripheral area PA. As illustrated in FIG. 23, the epitaxial growth of silicon and germanium is performed, at the memory area MR and the stepped wiring area CR, at a predetermined proportion to deposit the silicon germanium layer 1002. As described above, instead of the epitaxial growth, other film forming methods such as the CVD method and the PVD method can be employed.

This second embodiment can also provide effects similarly to those in the first embodiment.

### Third Embodiment

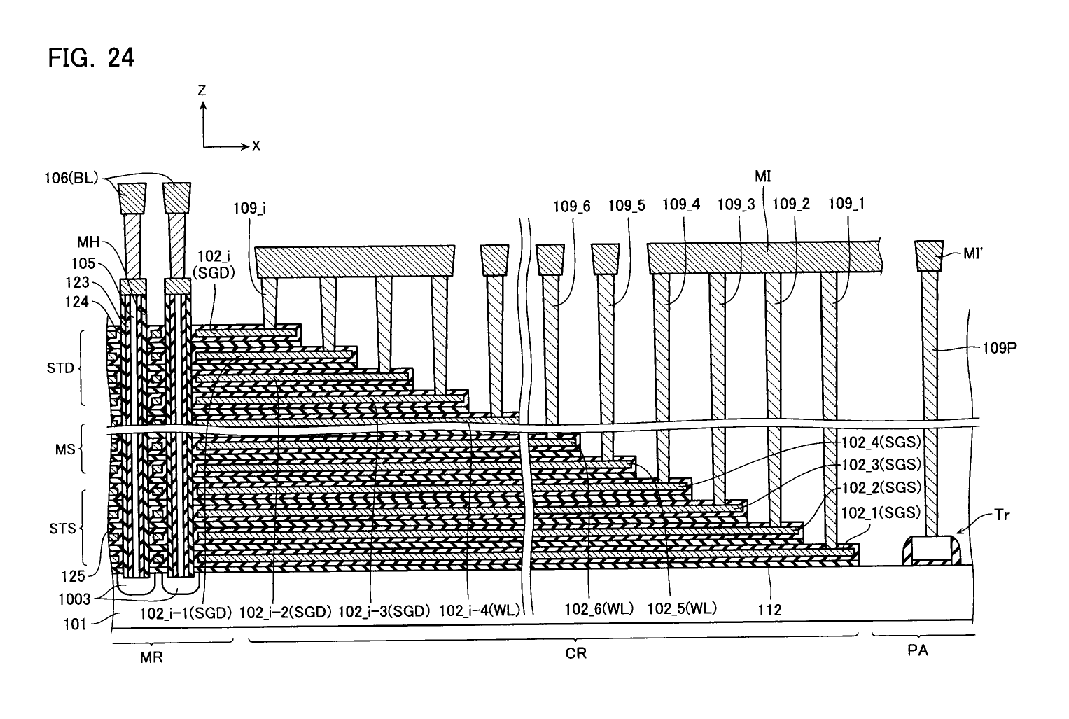

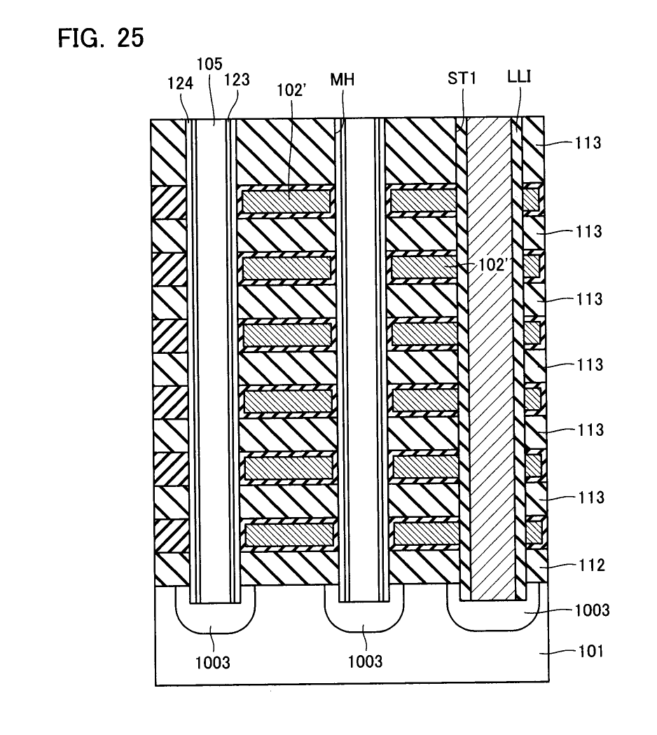

Next, the following describes a semiconductor memory device according to the third embodiment with reference to FIG. 24 and FIG. 25. In this third embodiment, the overall structure of the semiconductor memory device is similar to that of the first embodiment (in FIG. 1 to FIG. 5). Therefore, the overlapped description will not be further elaborated here. Note that this third embodiment differs from the first embodiment in the structure of the silicon germanium layer disposed below the conductive layer 102.

As illustrated in FIG. 24 and FIG. 25, this third embodiment includes the silicon germanium layers 1003 only at areas below the memory holes MH (below the memory columnar bodies 105) and areas below the slits ST1 (the source contact LI) and ST2. In this respect, the third embodiment differs from the first embodiment in that the silicon germanium layer is disposed at substantially the entire lower area at the memory area MR and the stepped wiring area CR. The silicon germanium layer 1003 of this third embodiment, for example, may be formed with germanium ion to be implanted through the memory holes MH and the slits ST1 and ST2. Instead of the ion implantation, the silicon germanium layers 1003 can also be formed at the areas illustrated in FIG. 24 and FIG. 25 by the epitaxial growth and the CVD method.

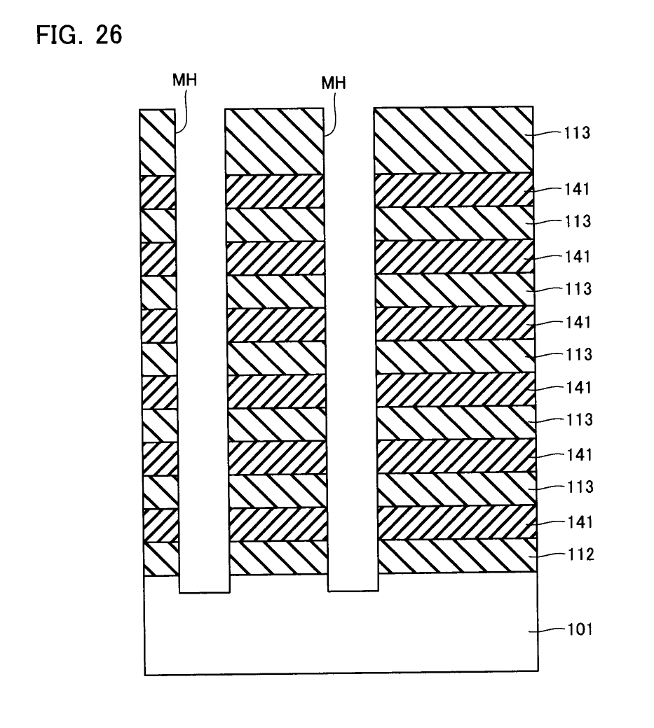

Next, the following describes the method for manufacturing this semiconductor memory device of the third embodiment with reference to FIG. 26 to FIG. 29. The manufacturing process for the memory cell array 1 is similar to that of the first embodiment. Accordingly, the following omits the description. The following describes only the procedure for forming the silicon germanium layer 1003.

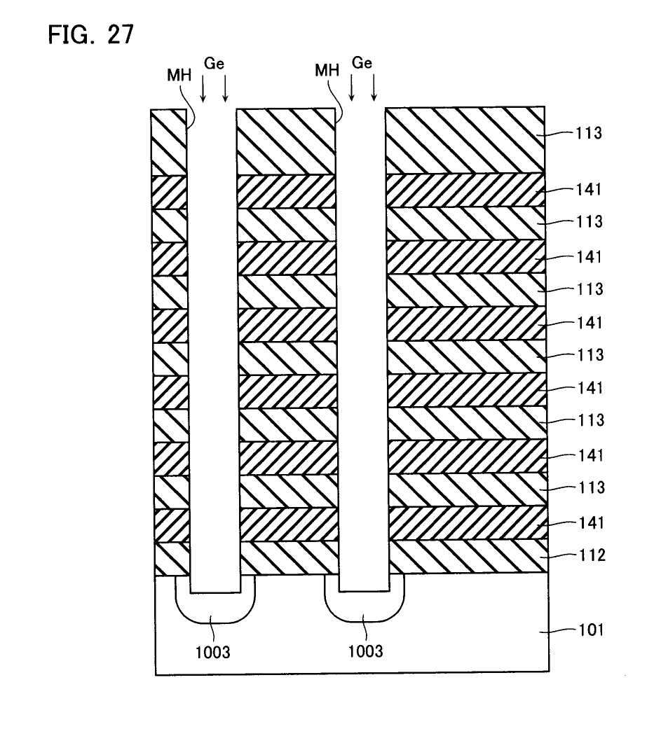

First, as illustrated in FIG. 26, the interlayer insulating films 113 and the sacrificial layers 141 are laminated at the memory area MR and the stepped wiring area CR to form a laminated body. Thereafter, similarly to the first embodiment, the memory holes MH passing through this laminated body is formed. After this, as illustrated in FIG. 27, the germanium ion is implanted to the semiconductor substrate 101 through these memory holes MH and the thermal process is performed. This forms the above-described silicon germanium layers 1003 limited to only the surface of the semiconductor substrate 101 at the bottoms of the memory holes MH.

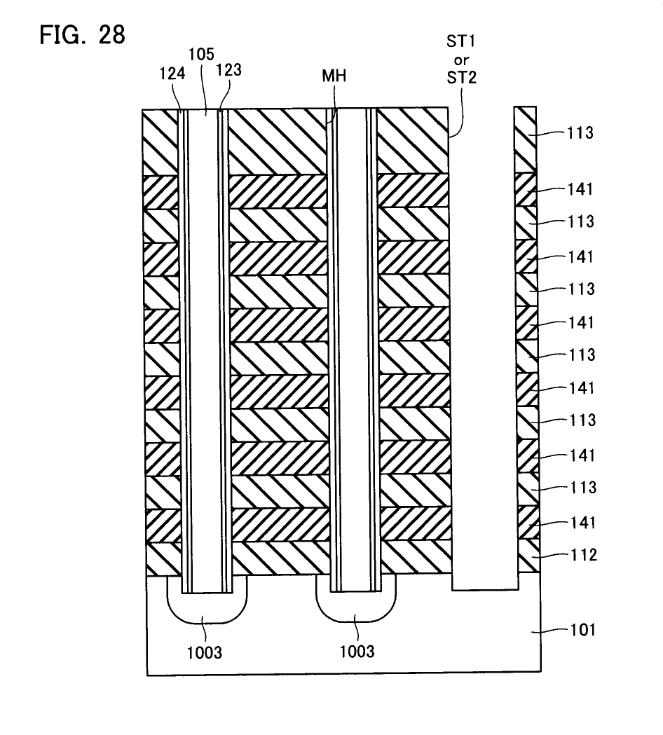

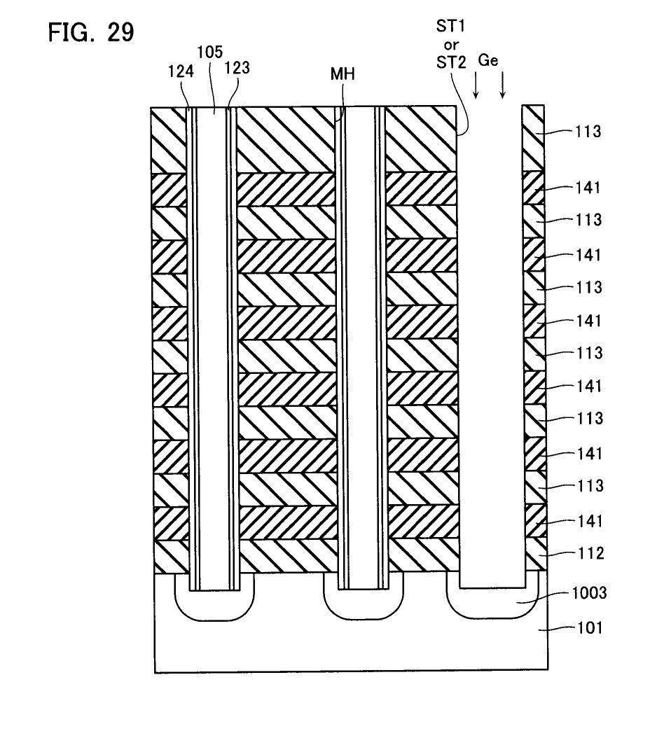

Afterwards, in the memory holes MH, the memory columnar bodies 105, the tunnel insulating layers 123, and the electric charge accumulating layers 124 are formed in the procedure similarly to the first embodiment. Then, as illustrated in FIG. 28, the slits ST1 and ST2 are formed at the lower areas of the memory area MR and the stepped wiring area CR. After this, as illustrated in FIG. 29, the germanium ion is implanted to the semiconductor substrate 101 through these slits ST1 and ST2 and the thermal process is performed. This forms the above-described silicon germanium layers 1003 limited to only the surface of the semiconductor substrate 101 at the bottoms of the slits ST1 and ST2.

This third embodiment can also provide effects similar to those in the first embodiment.

### OTHERS

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above-described embodiments use the silicon germanium layer as the base layer as an example. However, instead of the germanium, the base layer can also be formed by adding tin (Sn) and lead (Pb), which are the IV group elements similar to the germanium. The addition of these other IV group elements generates the compressive stress similar to the silicon germanium layer, also ensuring restraining the warping of the substrate.

What is claimed is:

1. A semiconductor memory device, comprising:
a semiconductor substrate made of silicon;
a laminated body disposed on the semiconductor substrate, the laminated body including a plurality of conductive layers and an interlayer insulating film, the interlayer insulating layer being disposed between the plurality of conductive layers;
a memory cell array that includes a pillar-shaped semiconductor layer and a memory gate insulating film, a peripheral area of the semiconductor layer being surrounded by the laminated body, the semiconductor layer extending with a first direction as a longitudinal direction, the memory gate insulating film being disposed between the pillar-shaped semiconductor layer and the laminated body, the memory gate insulating film including an electric charge accumulating film;
a stepped portion disposed at an end of the laminated body, the stepped portion whose positions of an end of a conductive layer at a lower layer and an end of a conductive layer at an upper layer in the first direction differ; and
a base layer formed under the laminated body, the base layer containing silicon and an IV group element different from the silicon.

2. The semiconductor memory device according to claim 1, wherein
the base layer is disposed under a surface of the semiconductor substrate.

3. The semiconductor memory device according to claim 1, wherein
the base layer is disposed over a surface of the semiconductor substrate.

4. The semiconductor memory device according to claim 1, further comprising:
a peripheral area that includes a transistor disposed at a surface of the semiconductor substrate; and
an interlayer insulating layer formed at a surface of the semiconductor substrate at the peripheral area, wherein
the base layer is formed on the semiconductor substrate including a side of the interlayer insulating layer.

5. The semiconductor memory device according to claim 1, wherein
the base layer is formed only under the pillar-shaped semiconductor layer.

6. The semiconductor memory device according to claim 1, further comprising
a peripheral area that includes a transistor disposed at a surface of the semiconductor substrate, wherein
the base layer is formed under the laminated body, meanwhile, the base layer being not formed at the peripheral area.

7. The semiconductor memory device according to claim 1, wherein
the IV group element is germanium.

8. The semiconductor memory device according to claim 7, wherein
the base layer is disposed under a surface of the semiconductor substrate.

9. The semiconductor memory device according to claim 7, wherein
the base layer is disposed over a surface of the semiconductor substrate.

10. The semiconductor memory device according to claim 7, further comprising:
a peripheral area that includes a transistor disposed at a surface of the semiconductor substrate; and
an interlayer insulating layer formed at a surface of the semiconductor substrate at the peripheral area, wherein
the base layer is formed on the semiconductor substrate including a side of the interlayer insulating layer.

11. The semiconductor memory device according to claim 7, wherein
the base layer is formed only under the pillar-shaped semiconductor layer.

12. The semiconductor memory device according to claim 7, further comprising
a peripheral area that includes a transistor disposed at a surface of the semiconductor substrate, wherein
the base layer is formed under the laminated body, meanwhile, the base layer being not formed at the peripheral area.

13. The semiconductor memory device according to claim 1, wherein
the base layer is made of a material that provides stress in an opposite direction from stress of the conductive layer.

14. A method for manufacturing a semiconductor memory device, comprising:
forming a base layer at a first region on a semiconductor substrate made of silicon, the base layer containing silicon and an IV group element different from the silicon;
forming a laminated body over the base layer, the laminated body including a plurality of sacrificial layers and an interlayer insulating layer, the interlayer insulating layer being disposed between the plurality of sacrificial layers;
forming a memory hole that passes through the laminated body, forming a memory gate insulating film and a semiconductor layer inside the memory hole, the memory gate insulating film including an electric charge accumulating film; and
after removing the sacrificial layers, forming conductive layers at voids formed by removing the sacrificial layers.

15. The method for manufacturing the semiconductor memory device according to claim 14, wherein
the base layer is formed by ion implantation with an IV group element or plasma doping to the semiconductor substrate.

16. The method for manufacturing the semiconductor memory device according to claim 14, wherein
the base layer is formed by forming a film with a material containing the IV group element and silicon on a surface of the semiconductor substrate.
